(19) United States
(12) Patent Application Publication
(10) Pub. No.: US 2025/0207022 A1
(43) Pub. Date: Jun. 26, 2025

(54) PHOSPHOR POWDER, PHOSPHOR-CONTAINING COMPOSITION, LIGHT-EMITTING ELEMENT, AND LIGHT-EMITTING DEVICE

(71) Applicant: Mitsui Mining & Smelting Co., Ltd., Tokyo (JP)

(72) Inventors: Hiroto KIMURA, Saitama (JP); Tsuyosi TAKAHASI, Saitama (JP); Ikuhiro OZAWA, Saitama (JP); Asuka SASAKURA, Saitama (JP)

(21) Appl. No.: 18/850,410

(22) PCT Filed: Mar. 28, 2023
(86) PCT No.: PCT/JP2023/012653

§ 371 Date: Sep. 24, 2024

(30) Foreign Application Priority Data
Mar. 28, 2022 (JP) 2022-052621

(51) Int. Cl. C09K 11/77; H10H 20/851

(52) U.S. Cl. CPC C09K 11/7731; H10H 20/8512

(57) ABSTRACT

Provided are a phosphor powder having a sufficiently high absorption rate and high internal quantum efficiency, a phosphor-containing composition, a light-emitting element, and a light-emitting device. The phosphor powder is such that the total volume frequency of particles having a grain size of less than 2.5 μm as measured by a laser diffraction scattering grain size distribution measurement method is 10% or greater, the total volume frequency of particles having a grain size of 2.5-10 μm is 10-90%, and the cumulative 50% diameter (D50) in the volume grain size distribution is 10.0 μm or less.

### TECHNICAL FIELD

The present invention relates to a phosphor powder, a phosphor-containing composition, a light-emitting element, and a light-emitting device.

### BACKGROUND ART

A light-emitting element including a combination of a phosphor and a near-ultraviolet or blue light-emitting diode (LED), which is a light source (excitation source), is widely used for a variety of light-emitting devices, such as lighting fixtures, cell-phone backlights, and displays.

In such light-emitting devices, the phosphor absorbs the light (emission) from the LED and emits light with a wavelength different from that of the absorbed light. This mechanism allows the emission of light with a color different from that of the LED emission. For example, a combination of a yellow phosphor and a blue LED allows the emission of white light. Such a white light-emitting element (white LED) is widely used for lighting fixtures and other applications.

Another combination of a green or red phosphor and a blue LED allows the emission of green or red light, and a light-emitting element with such a combination is used for displays and other applications.

For example, Patent Document 1 discloses a green phosphor material for LEDs, which includes a crystal matrix including one or a combination of two or more of Sr, Ba, and Ca and including Ga and S; and a luminescent center (see claim 1 of Patent Document 1). It also discloses the use of such a green phosphor for lighting fixtures and displays (see paragraph [0001] of Patent Document 1). Patent Document 2 discloses that a material including: β sialon represented by the formula Si_{6-z}Al_{z}O_{z}N_{8-z}; and a Eu solid solution can be used to form a light-emitting device, such as a light-emitting diode including a blue or ultraviolet light-emitting diode chip (see claim 1 and paragraph [0001] of Patent Document 2).

In recent years, as the display technology has advanced, much attention has focused on mini-LED displays and micro-LED displays. A micro-LED display includes independent R (red), G (green), and B (blue) light-emitting diodes (LEDs), which form sub-pixels in the display. Such a micro-LED display has an advantage such as the ability to produce high-brightness, high-contrast-ratio images at high response speed with low power consumption as compared to a liquid crystal panel. In contrast to an organic EL display, it is also characterized by its ability to display high-brightness images with no alternation-induced burn-in.

Patent Document 3 discloses a micro-LED display device including a micro-LED driving board and a micro-LED panel (see claim 1 of Patent Document 3). Patent Document 3 also discloses that the micro-LED panel includes a light-emitting structure (including a plurality of micro-LED pixels); a growth substrate on the light-emitting structure; a plurality of partitions on the growth substrate; and R/G/B color conversion materials (or R/G/B phosphors) each disposed between a pair of the partitions to convert the wavelength of light emitted from each light-emitting element (pixel) to another wavelength (see paragraphs [0022] and [0034] of Patent Document 3).
Patent Document 1: PCT International Publication No. WO2009/136505
Patent Document 2: Japanese Unexamined Patent Application, Publication No. 2012-056804
Patent Document 3: Japanese Unexamined Patent Application, Publication No. 2018-182282

### DISCLOSURE OF THE INVENTION

### Problems to be Solved by the Invention

Phosphors for LEDs, especially for micro-LED displays, should have high emission intensity and high emission color quality. The higher the emission intensity, the more efficient the color conversion of the LED emission. High internal quantum efficiency (IQE) and high external quantum efficiency (EQE) are important for that purpose. To achieve high emission color quality, it is important to have a narrow emission spectrum and not to transmit blue light. For those purposes, a high absorption rate (Abs) is desired. As used herein, the term “external quantum efficiency” refers to the efficiency with which, when irradiated with a ray, a phosphor converts the ray to another ray, and the term “internal quantum efficiency” refers to the efficiency with which upon absorbing a ray, a phosphor converts the ray to another ray. The term “absorption rate” refers to the ratio of the quantity of light absorbed into a phosphor to the quantity of light applied to the phosphor. The external quantum efficiency (EQE), the internal quantum efficiency (IQE), and the absorption rate (Abs) satisfy the relationship of Formula (1) below.

$$\begin{matrix}[ Math . 1 ] & \\ ( E Q E ) = ( I Q E ) \times ( Abs ) & ( 1 )\end{matrix}$$

As shown in Formula (1) above, the external quantum efficiency (EQE) of a phosphor is expressed as the product of the internal quantum efficiency (IQE) and the absorption rate (Abs). This suggests that a good phosphor material should have both a high internal quantum efficiency and a high absorption rate.

It is particularly important that a phosphor for micro-LED displays should have both a high quantum efficiency and a high absorption rate in contrast to a conventional phosphor for white LEDs. In this regard, as shown in FIG. 1, a conventional white LED including a combination of a blue LED and a yellow phosphor layer is configured to transmit some of the LED emission through the phosphor when it produces white light. The phosphor layer is as thick as several millimeters and there is no need to absorb the entire LED emission, which means that there is no need to increase the absorption rate so much. In contrast, as shown in parts A and B of FIG. 2, green and red phosphor layers for a micro-LED display should ideally absorb the entire blue emission from the LED when excited to perform color conversion. In addition, those phosphor layers should be as thin as tens to hundreds of micrometers. This means that even if thin, such phosphor layers should absorb a sufficient quantity of the emission, and for that purpose, it is important that the phosphors should have a high absorption rate.

Meanwhile, the internal quantum efficiency and the absorption rate of a conventional phosphor powder are known to increase as its particle size increases, and thus, a technique for removing finer particles has been proposed. For example, Patent Document 1 discloses that limiting D10 of phosphor particles to not less than 4.5 μm can increase their absorption rate to 70% or more and increase their external quantum efficiency (see paragraph [0013] of Patent Document 1). Patent Document 2 discloses that the average particle diameter D50 is preferably 5 μm or more and 30 μm or less; particles with too small an average particle diameter D50 may have low emission efficiency; and after particle size adjustment, fine particles of 5 μm or less are removed by classification in water (see paragraphs [0023] and [0031] of Patent Document 2).

However, the inventors' study has revealed that even fine phosphor particles can have a high absorption rate in an LED package (cell) filled with a composition containing the phosphor particles dispersed in a resin while course particles can have a higher absorption rate when present in a powder alone. As a result of further studies, the inventors have created a phosphor-containing composition including fine particles and medium-diameter particles and have found that when filled in a package, such a composition can have a sufficiently high absorption rate and a high internal quantum efficiency.

It is an object of the present invention, which has been completed based on such findings, to provide a phosphor powder, a phosphor-containing composition, a light-emitting element, and a light-emitting device each having a sufficiently high absorption rate and a high internal quantum efficiency.

### Means for Solving the Problems

The present invention provides a phosphor powder including, as measured by laser diffraction scattering particle size distribution measurement: particles with a particle diameter of less than 2.5 μm at a cumulative volume frequency of 10% or more; and particles with a particle diameter of 2.5 μm or more and 10.0 μm or less at a cumulative volume frequency of 10% or more and 90% or less, the phosphor powder having a volume particle size distribution with a 50% cumulative diameter (D50) of 10.0 μm or less.

The present invention also provides a phosphor-containing composition including the phosphor powder.

In the specification, the word “to” between two numerical values indicates that the specified range is inclusive of the two numerical values. In other words, the expression “X to Y” is interchangeable with “X or more and Y or less”.

### Effects of the Invention

The present invention provides a phosphor powder, a phosphor-containing composition, a light-emitting element, and a light-emitting device each having a sufficiently high absorption rate and a high internal quantum efficiency.

### BRIEF DESCRIPTION OF THE DRAWINGS

FIG. 1 is a diagram provided to describe a conventional phosphor for white LEDs;

FIG. 2 is a diagram provided to describe phosphors for micro-LEDs;

FIG. 3 is a graph showing the particle size distribution (volume frequency distribution curve) of phosphor powders (Example 1 and Comparative Example 1);

FIG. 4 is a graph showing the particle size distribution (volume frequency distribution curve) of phosphor powders (Example 2 and Comparative Example 1);

FIG. 5 is a graph showing the particle size distribution (volume frequency distribution curve) of phosphor powders (Example 3 and Comparative Example 1);

FIG. 6 is a graph showing the particle size distribution (volume frequency distribution curve) of phosphor powders (Example 4 and Comparative Example 1);

FIG. 7 is a graph showing the particle size distribution (volume frequency distribution curve) of phosphor powders (Example 5 and Comparative Example 1);

FIG. 8 is a graph showing the particle size distribution (volume frequency distribution curve) of phosphor powders (Example 6 and Comparative Example 1);

FIG. 9 is a graph showing the particle size distribution (volume frequency distribution curve) of phosphor powders (Example 7 and Comparative Example 1);

FIG. 10 is a graph showing the particle size distribution (volume frequency distribution curve) of phosphor powders (Example 8 and Comparative Example 1);

FIG. 11 is a graph showing the particle size distribution (volume frequency distribution curve) of phosphor powders (Example 9 and Comparative Example 1);

FIG. 12 is a graph showing the particle size distribution (volume frequency distribution curve) of phosphor powders (Example 10 and Comparative Example 1);

FIG. 13 is a graph showing the particle size distribution (volume frequency distribution curve) of phosphor powders (Example 11 and Comparative Example 1); and

FIG. 14 is a graph showing the particle size distribution (volume frequency distribution curve) of phosphor powders (Example 12 and Comparative Example 1).

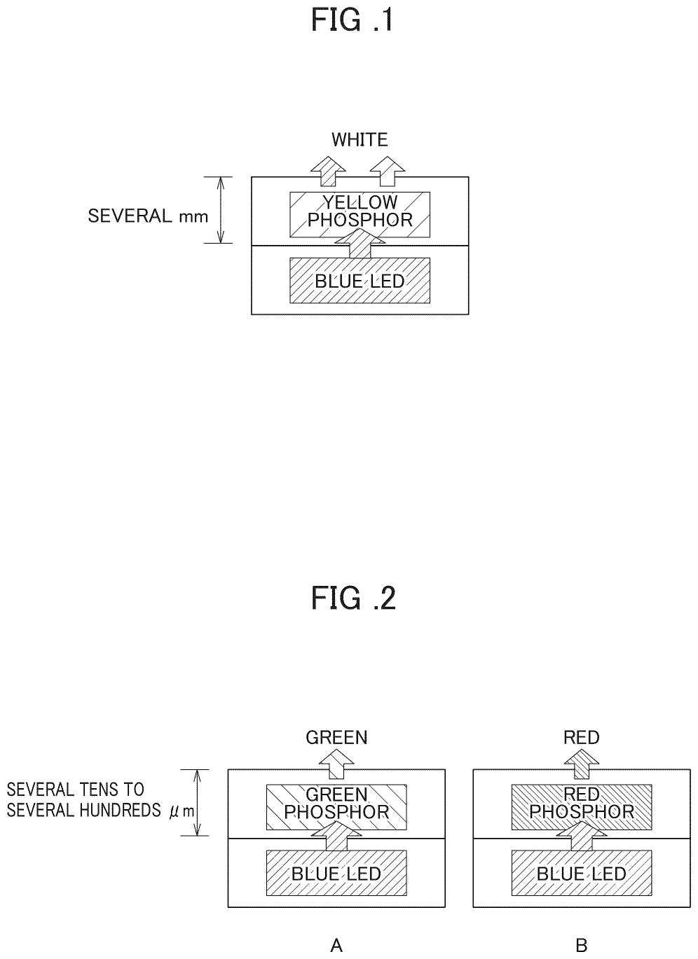

### PREFERRED MODE FOR CARRYING OUT THE INVENTION

Specific embodiments of the present invention (hereinafter referred to as “embodiments”) will be described. It will be understood that the embodiments below are not intended to limit the present invention and may be altered or modified in various ways without departing from the gist of the present invention.

### 1. Phosphor Powder

An embodiment is directed to a phosphor powder including, as measured by laser diffraction scattering particle size distribution measurement: particles with a particle diameter of less than 2.5 μm (hereafter also referred to as “fine particles”) at a cumulative volume frequency of 10% or more; and particles with a particle diameter of 2.5 μm or more and 10.0 μm or less (hereafter also referred to as “medium-diameter particles”) at a cumulative volume frequency of 10% or more and 90% or less. The phosphor powder also has a volume particle size distribution with a 50% cumulative diameter (D50) of 10.0 μm or less. The phosphor powder of this embodiment includes the fine particles and the medium-diameter particles in an appropriate ratio.

The phosphor powder has a relatively broad particle size distribution with a relatively small D50. Such features allow the phosphor powder to have a high absorption rate and a high internal quantum efficiency. As used herein, the term “powder” refers to a group of multiple particles having fluidity as a whole. Multiple particles may also be said to be components of a powder.

In the phosphor powder, the cumulative volume frequency of particles with a particle diameter of less than 2.5 μm (fine particles) is limited to 10% or more. Such a relatively high content of the fine particles allows the phosphor-containing composition in an LED package to have a high absorption rate. In contrast, a content of the fine particles of less than 10% may provide a low absorption rate and make it impossible to produce a phosphor material with high emission color quality. The cumulative volume frequency of the fine particles is preferably 20% or more, more preferably 30% or more, even more preferably 40% or more. On the other hand, an excessively high content of the fine particles may result in a low content of the medium-diameter particles and provide a low internal quantum efficiency. The cumulative volume frequency of the fine particles is preferably 90% or less, more preferably 80% or less, even more preferably 70% or less. The cumulative volume frequency of the fine particles may be determined by a process including: measuring the particle size distribution of the phosphor powder to plot a volume (mass) frequency distribution curve; and adding up the frequencies of particles with a particle diameter of less than 2.5 μm in the frequency distribution curve.

The cumulative volume frequency of particles with a particle diameter of 2.5 μm or more and 10 μm or less (medium-diameter particles) in the phosphor powder is limited to 10% or more and 90% or less. An LED package containing the medium-diameter particles at a content increased to some extent can have a high internal quantum efficiency. In contrast, a content of the medium-diameter particles of less than 10% may provide a low internal quantum efficiency and make it difficult to produce a phosphor material with a high emission intensity. The cumulative volume frequency of the medium-diameter particles is preferably 15% or more, more preferably 20% or more, even more preferably 30% or more. On the other hand, an excessively high content of the medium-diameter particles may result in a low content of the fine particles and provide a low absorption rate. The cumulative volume frequency of the medium-diameter particles is preferably 80% or less, more preferably 70% or less, even more preferably 60% or less.

The phosphor powder preferably contains particles with a particle diameter of more than 10 μm (coarse particles) at a cumulative volume frequency of 0% or more and 50% or less. The phosphor powder with a coarse particle content of 50% or less can be successfully filled in an LED package and ensured to be uniformly filled in the LED package. The cumulative volume frequency of the coarse particles is preferably 40% or less, more preferably 30% or less, even more preferably 20% or less.

The D50 in the volume particle size distribution of the phosphor powder is limited to 10.0 μm or less. The conventional technique includes removing small particles from a phosphor powder to achieve a particle size distribution containing only large particles and thereby to improve the quantum efficiency. In contrast, the phosphor powder of this embodiment has a small average particle diameter and a broad particle size distribution. When used to form a phosphor-containing composition as described below, the phosphor powder with such features can be densely packed in the composition.

Thus, an LED package filled with such a composition can have an improved absorption rate and an improved internal quantum efficiency. Such a composition will make it easy to design thin members required for mini-LED or micro-LED display applications. A D50 of more than 10.0 μm may provide a low absorption rate. The D50 is preferably 9.0 μm or less, more preferably 8.0 μm or less, even more preferably 7.0 μm or less. On the other hand, an excessively small D50 may lead to a low medium-diameter particle content and provide a low internal quantum efficiency. The D50 is preferably 1.0 μm or more, more preferably 2.0 μm or more, even more preferably 3.0 μm or more. The D50 can be determined by a process including: determining the volume (mass) cumulative distribution curve of the phosphor powder; and determining the diameter at 50% in the cumulative distribution curve.

A volume frequency distribution curve may be plotted with the common logarithm of particle diameter on the horizontal axis, volume frequency on the vertical axis, and the maximum volume frequency being normalized to 1. The peak area, which is the area enclosed by such a volume frequency distribution curve and the horizontal axis, is preferably 12 or more, and more preferably 13 or more.

In this regard, the peak area is a measure of whether the width of the particle size distribution is wide or narrow. The smaller the peak area, the narrower the particle size distribution, and the larger the peak area, the wider the particle size distribution. The phosphor powder with a broad particle size distribution can contain particles with particle diameters different from the desired particle diameter. When filled in an LED package, the phosphor powder with such features can have both a higher absorption rate and a higher internal quantum efficiency. For high absorption rate and high quantum efficiency, the peak area is preferably as large as possible. The peak area is preferably 16 or more, and more preferably 18 or more. For a good balance between high absorption rate and high internal quantum efficiency, the peak area preferably has an upper limit of 80.

The peak area may be determined as follows. First, the volume frequency distribution curve of the phosphor powder is determined. The frequency distribution curve is plotted with the common logarithm (with a radix of 10) of particle diameter (in units of μm) on the horizontal axis and volume-based frequency (volume frequency) on the vertical axis. The frequency distribution curve is then normalized to have a maximum value of 1. The area enclosed by the frequency distribution curve and the horizontal axis is then calculated to be the peak area.

As measured by laser diffraction scattering particle size distribution measurement, the volume particle size distribution preferably has a particle size distribution ratio of 0.7 or more, more preferably a particle size distribution ratio of more than 0.8, in which the particle size distribution ratio is calculated as (D80−D20)/D50 from the 20% cumulative diameter (D20), the 50% cumulative diameter (D50), and the 80% cumulative diameter (D80) of the volume particle size distribution. The particle size distribution ratio ((D80−D20)/D50) is a measure of whether the particle size distribution is wide or narrow. The smaller the particle size distribution ratio, the narrower the width of the particle size distribution, and the larger the particle size distribution ratio, the wider the width of the particle size distribution. For high absorption rate and high quantum efficiency, the particle size distribution ratio is preferably as large as possible. The particle size distribution ratio is preferably 1.0 or more, more preferably 1.2 or more.

D20 is preferably 1 μm or more and 5 μm or less, more preferably 1.5 μm or more and 3 μm or less, provided that D20 is smaller than D50 or D80. D80 is preferably 3 μm or more and 13 μm or less, more preferably 5 μm or more and 10 μm or less, provided that D80 is larger than D20 or D50.

The phosphor powder of this embodiment may have any material composition as long as it has the ability to emit fluorescence. Fluorescent materials include a crystal matrix and a luminescent center (activator). In many fluorescent materials, the suitable crystal matrix contains several percent of the luminescent center in the form of a solid solution. Known fluorescent materials include oxides, sulfides, oxysulfides, nitrides, and oxynitrides, any of which may be used.

Examples of oxide-based fluorescent materials include (Y, Gd, Lu)₃ (Al,Ga)₅O₁₂:Ce³⁺, (Ba, Sr, Ca)₂SiO₄:Eu²⁺, (Ba, Sr, Ca)₃MgSi₂O₈:Eu²⁺, CaAl₁₂O₁₉:Mn⁴⁺, Ca₃Sc₂Si₃O₁₂:Ce³⁺, CaSc₂O₄:Ce³⁺, (Ba,Sr)₃SiO₅:Eu²⁺, Li₂SrSiO₄:Eu²⁺, Ba₉Sc₂Si₆O₂₄:Eu²⁺, Ca₃Si₂O₇:Eu²⁺, LiSrPO₄:Eu²⁺, CaLa₄Si₃O₁₃:Eu³⁺, Ba₂Gd₃Li₃MosO₃₂:Eu³⁺, and BaMgAl₁₀O₁₇:Eu²⁺, Mn²⁺.

Examples of sulfide-based fluorescent materials include (Ba, Sr, Ca) Ga₂S₄:Eu²⁺, (Ba, Sr, Ca) Ga₂S₄:Ce³⁺, (Sr,Ca)S:Eu²⁺, (Sr,Cd)S:Eu²⁺, and ZnS:Cu.

Examples of oxysulfide-based fluorescent materials include (La,Y)₂O₂S:Eu³⁺, La(Ca,Sr) Ga₃S₆O:Eu²⁺, and La₂O₃S:Eu³⁺.

Examples of nitride-based fluorescent materials include (Ba, Sr, Ca)₂Si₅N₈:Eu²⁺, (Ba, Ca, Sr)AlSiN₃:Eu²⁺, La₃Si₆N₁₁:Ce³⁺, (Ba, Sr, Ca) LiAl₃N₄:Eu²⁺, Sr(Mg₃SiN₄):Eu²⁺, and (Ba,Sr)₂Si₅N₈:Eu²⁺.

Examples of oxynitride-based fluorescent materials include Eu-containing a sialons, Eu-containing B sialons, Ba₉Sc₃Si₆O₂₁N₃:Eu²⁺, Ba₃Si₆O₁₂N₂:Eu²⁺, BaSi₂O₂N₂:Eu²⁺, and (Ba, Sr, Ca) AlSi(ON)₃:Eu²⁺.

Examples of other fluorescent materials include Sr₁₀(PO₄)₆C₁₂:Eu²⁺ and K₂ (Si, Ge, Ti) F₆:Mn⁴⁺.

In a preferred mode, the phosphor powder includes a crystal matrix including gallium (Ga), sulfur (S), and at least one metal element selected from the group consisting of barium (Ba), strontium (Sr), and calcium (Ca); and a luminescent center, as shown above in the list of the compositions of sulfur-based fluorescent materials. The luminescent center preferably includes at least one element selected from the group consisting of europium (Eu), cerium (Ce), manganese (Mn), and samarium (Sm). For excitation with higher internal quantum efficiency by blue light from LED, the luminescent center preferably includes Eu, more preferably includes divalent Eu ions (Eu²⁺), and even more preferably includes only Eu²⁺. More preferably, the phosphor powder includes crystals of the formula:MGa₂S₄:Eu²⁺ (wherein M is at least one element selected from the group consisting of Ba, Sr, and Ca). When excited by light with a wavelength between the near-ultraviolet and blue regions (about 300 nm to about 510 nm), the phosphor powder having such a composition will emit green light.

In another preferred mode, the phosphor powder includes a crystal matrix including sulfur (S) and at least one metal element selected from the group consisting of barium (Ba), strontium (Sr), and calcium (Ca); and a luminescent center, as shown above in the list of the compositions of sulfur-based fluorescent materials. The luminescent center preferably includes at least one element selected from the group consisting of europium (Eu), cerium (Ce), manganese (Mn), and samarium (Sm). More preferably, the phosphor powder includes crystals of the formula:MS:Eu²⁺ (wherein M is at least one element selected from the group consisting of Ba, Sr, and Ca). When excited by light with a wavelength between the ultraviolet and visible regions (about 250 nm to about 610 nm), the phosphor powder having such a composition will emit red light.

For higher emission intensity, the content of the luminescent center in the phosphor powder is preferably adjusted such that the ratio (XA/(XM+XA)) of the molar amount XA of the element A to the sum (XM+XA) of the molar amounts of the elements M and A is 0.05 or more, more preferably 0.07 or more, even more preferably 0.10 or more. For the prevention of concentration quenching, XA/(XM+XA) is preferably 0.30 or less, more preferably 0.25 or less, even more preferably 0.20 or less.

The phosphor particle may or may not have a surface coating layer. However, the phosphor particle having a surface coating layer can have improved durability, such as improved moisture resistance. In order to provide the phosphor material with improved durability and to maintain the ability of the phosphor material to produce good emission, the coating layer preferably includes at least one of inorganic compounds including an oxide such as silicon dioxide (SiO₂), zinc oxide (ZnO), aluminum oxide (Al₂O₃), titanium oxide (TiO₂), and/or boron (B)-containing oxide and a metal sulfate such as barium sulfate (BaSO₄).

When filled in an LED package, the phosphor powder of this embodiment can exhibit a sufficiently high absorption rate and a sufficiently high internal quantum efficiency. This means that the external quantum efficiency is high, which is the product of the absorption rate and the internal quantum efficiency. Thus, the resulting phosphor material can have high emission intensity and high emission color quality.

### 2. Method for Producing the Phosphor Powder

In an embodiment, the phosphor powder may be produced by any method capable of satisfying the requirements described above. Preferably, the phosphor powder is produced by a process including: synthesizing a coarse phosphor powder from starting materials; and subjecting the coarse phosphor powder to particle size adjustment, such as milling and classification. An example of a preferred method for producing the phosphor powder will be described below.

First, at least one of a strontium (Sr) source, a barium (Ba) source, or a calcium (Ca) source, and a gallium (Ga) source, a sulfur (S) source, and a europium (Eu) source are weighed and mixed to form a raw material mixture. The strontium (Sr) source, the barium (Ba) source, and the calcium (Ca) source may each be an oxide, composite oxide, and/or carbonate of each element. The gallium (Ga) source may be an oxide (Ga₂O₃, GaO). The sulfur (S) source may be strontium sulfide (SrS), barium sulfide (BaS), calcium sulfide (CaS), sulfur (S), silicon sulfide (SiS₂), cerium sulfide (Ce₂S₃), or hydrogen sulfide (H₂S) gas. The europium (Eu) source may be a europium compound such as europium fluoride (EuF₃), europium oxide (Eu₂O₃), or europium chloride (EuCl₃).

For the adjustment of the emission wavelength of the phosphor powder and for the improvement of emission efficiency, a rare earth element, such as praseodymium (Pr) or samarium (Sm) may be added to the raw materials. For the improvement of excitation efficiency, at least one element selected from rare earth elements including scandium (Sc), lanthanum (La), gadolinium (Gd), and lutetium (Lu) may also be added as a sensitizer to the raw materials. It should be noted that the content of each of such additives should preferably be 5 mol % or less based on the amount of strontium (Sr). A content of each of such elements of more than 5 mol % may lead to precipitation of a large amount of different phases and to a significant reduction in brightness. An alkali metal element, monovalent metal cations, such as silver ions (Ag⁺), or ions of halogen such as chlorine (Cl), fluorine (F), or iodine (I) may also be added as a charge compensation agent to the raw materials. For charge compensation effect and brightness, the content of such an additive is preferably substantially the same as the content of the aluminum family element or the rare earth element.

The raw materials may be mixed by any suitable method. The mixing method may be either dry or wet mixing. A dry mixing method may include mixing the raw materials in a paint shaker, a ball mill, or any other mixing machine using zirconia balls as media; and optionally drying the mixture to form a raw material mixture. A wet mixing method may include adding a solvent such as water to the raw materials to form a suspension; mixing the suspension in a paint shaker, a ball mill, or any other mixing machine using zirconia balls as media; then removing the media using a sieve or any other means; and removing the solvent from the suspension by a drying method, such as reduced pressure drying or vacuum drying.

The resulting raw material mixture is then fired to form a fired product. Before the firing, the raw material mixture may or may not be milled, classified, and/or dried as needed.

The firing is preferably performed at a temperature of 1,000° C. or more. At 1,000° C. or higher, the firing can be performed in a sufficient and uniform manner. The upper limit of the firing temperature will depend on the endurance temperature of the firing furnace and the production temperature and cannot be defined uniquely. However, the firing is preferably performed at a temperature of 1,000° C. or more and 1,200° C. or less. The firing time may be determined depending on the firing temperature. However, the firing time is preferably about 2 hours or more and about 24 hours or less.

The firing atmosphere may be inert or reducing gas. For example, the firing atmosphere may be an argon atmosphere, a nitrogen atmosphere, a sulfur atmosphere, a hydrogen gas-containing argon atmosphere, a hydrogen gas-containing nitrogen atmosphere, or a hydrogen sulfide atmosphere. In particular, the firing is preferably performed under a hydrogen sulfide atmosphere.

When the raw material mixture contains a sulfur (S) source, it may be fired under an atmosphere of hydrogen sulfide, carbon disulfide, or inert gas. During the firing, hydrogen sulfide or carbon disulfide, if used, is converted to another sulfur compound, which is effective in suppressing the decomposition of the product. On the other hand, when free of any sulfur source, the raw materials are preferably fired under a sulfur-containing atmosphere, such as hydrogen sulfide or carbon disulfide.

The fired product is then milled into a powder. The milling may be performed using a known milling machine, such as a ball mill, a stamp mill, a jet mill, a grinding mixer, and/or a paint shaker. If necessary, the milled product resulting from the milling may be subjected to classification. The classification may be performed using a known means, such as a sieve or an airflow classifier. The phosphor powder is produced as described above.

In this embodiment, it is desirable to effectively use the fine particles resulting from the milling and classification. In other words, a phosphor-containing composition including not only the medium-diameter particles but also the fine particles should be produced. Such a composition will have a sufficiently high absorption rate and a high internal quantum efficiency.

In the production method of this embodiment, it is important to control the particle size distribution of the phosphor powder resulting from the milling. Specifically, the particle size of the phosphor powder should be controlled such that it includes the fine particles at a cumulative volume frequency of 10% or more and the medium-diameter particles at a cumulative volume frequency of 10% or more and 90% or less and has a D50 of 10.0 μm or less.

The particle size distribution may be controlled by any method. The particle size distribution may also be controlled by controlling the milling conditions or the classification conditions. For example, in a case where the milling is performed using a ball mill, the particle size distribution may be controlled by controlling the ball milling conditions including milling time, ball mill rotation speed, medium (ball) size, and medium (ball) filling rate. In a case where the milling is performed using a jet mill, the particle size distribution may be controlled by controlling the jet milling conditions including milling pressure and supplied gas type. In a case where classification is performed, the particle size distribution may be controlled by selecting the size of the sieve aperture and controlling the classification point (cut point).

### 3. Phosphor-Containing Composition

An embodiment is directed to a phosphor-containing composition including the phosphor powder described above. The phosphor-containing composition may also contain an additional component in addition to the phosphor powder. Such an additional component is preferably a resin and/or an organic solvent. The phosphor-containing composition including the phosphor powder and a resin can be molded to form a light-emitting element. The phosphor-containing composition containing the phosphor powder and an organic solvent can be applied to the surface of an excitation source to form a light-emitting element directly on the excitation source.

For example, the resin may be at least one selected from thermoplastic resin, thermosetting resin, ionizing radiation curable resin, and two-component curable resin. Examples of the thermoplastic resin include polyolefin resins, such as polyethylene and polypropylene; polyester resins, such as polyethylene terephthalate and polybutylene terephthalate; polycarbonate resins; polyacrylic resins, such as polyacrylic acid, polyacrylate, polymethacrylic acid, and polymethacrylate; polyvinyl resins, such as polystyrene and polyvinyl chloride; cellulose resins, such as triacetyl cellulose; and urethane resins, such as polyurethane. Examples of the thermosetting resin include silicone resins, phenolic resins, epoxy resins, melamine resins, urea resins, unsaturated polyester resins, alkyd resins, polyurethane resins, and polyimide resins. Examples of the ionizing radiation curable resin include acrylic resins, urethane resins, vinyl ester resins, and polyester alkyd resins. These resins may include not only a polymer but also an oligomer and a monomer. Examples of the two-component curable resin include epoxy resins.

### 4. Light-Emitting Element

An embodiment is directed to a light-emitting element including the phosphor material described above and an excitation source. The excitation source serves to emit light toward the phosphor material and thereby to excite the phosphor material. The excitation source is preferably an LED with a wavelength of 250 nm or more and 510 nm or less. The phosphor material and the excitation source may be disposed at any locations as long as the light from the excitation source enters the phosphor material. Preferably, however, the phosphor material is disposed immediately above the excitation source. Such an arrangement allows the phosphor material to absorb the entire light from the excitation source during color conversion. For example, the light-emitting element may be used to form a micro-LED display including packages. In such a case, each of the packages preferably includes an LED (excitation source) at the bottom; and the phosphor material disposed above the LED.

The light-emitting element of this embodiment has such features as high emission intensity and high emission color quality. Therefore, the light-emitting element of this embodiment is suitable for use in mini-LED displays or micro-LED displays.

### 5. Light-Emitting Device

An embodiment is directed to a light-emitting device including the light-emitting element described above. In the light-emitting device of this embodiment, the light-emitting element has such features as high emission intensity and high emission color quality. Therefore, the light-emitting device of this embodiment is suitable for use in mini-LED displays or micro-LED displays.

### EXAMPLES

The present invention will be described in more detail with reference to the following examples. It should be noted, however, that the following examples are not intended to limit the present invention.

### (1) Preparation of Phosphor Powder and Phosphor-Containing Composition

### Example 1

Barium sulfide (BaS), strontium sulfide (SrS), europium sulfide (EuS), and gallium sulfide (Ga₂S₃) were provided and weighed such that the amounts of Ba, Sr, Eu, and Ga were in a molar ratio of 0.22:0.65:0.13:2.00. The weighed materials were then mixed in a paint shaker with 3 mm diameter zirconia balls for 100 minutes to form a raw material composition. The resulting raw material composition was then fired under a hydrogen sulfide (H₂S) atmosphere under the conditions of a rate of temperature increase of 5° C./minute, a firing temperature of 1,100° C., and a firing time of 6 hours to form a fired product.

To a 500 ml alumina pot were added 50 g of the resulting product and 50 g of ethanol to form a mixture with a solid concentration of 50 mass %. The mixture was then subjected to wet milling using a ball mill to form a milled product. The balls used were zirconia balls with a diameter of 15 mm, 10 mm, 7 mm, or 3 mm. The balls were rotated at a speed of 300 rpm. The milling conditions were as shown in Table 1. The resulting milled product, which was a phosphor powder, was subjected to evaluation.

Ten parts by mass of the resulting phosphor powder was mixed with 100 parts by mass of a silicone resin. The mixture was kneaded and dispersed to give a dispersion composition. Subsequently, the resulting dispersion composition was formed into a 100 μm-thick coating, which corresponds to a phosphor-containing composition. The coating was then subjected to evaluation.

### Examples 2 to 6 and 8

The milling conditions were as shown in Table 1. Phosphor powders and phosphor-containing compositions were prepared as in Example 1, except for the conditions shown in Table 1, and then subjected to evaluation.

### Example 7

The milling was performed using a jet mill (MC DecJet® 30 (Dec Group)). The gas pressure was 0.4 MPa, and the feed gas was N₂. A phosphor powder and a phosphor-containing composition were prepared as in Example 1, except for the above conditions, and then subjected to evaluation.

### Examples 9 to 12

Calcium carbonate (CaCO₃) was weighed and milled using a bead mill. The milled product was dried and then fired in a hydrogen sulfide gas atmosphere at 850° C. for 4 hours. Europium oxide (Eu₂O₃) was then added to the fired product, and the mixture was fired under an argon (Ar) gas atmosphere under the conditions of a rate of temperature increase of 5° C./minute, a firing temperature of 1,000° C., and a firing time of 4 hours to form a fired product of the formula:CaS:Eu. In this process, the proportions of the raw materials were adjusted such that the europium (Eu) concentration (XA)/(XM+XA) was 0.3 mol %.

To a 500 ml alumina pot were added 50 g of the resulting product and 50 g of ethanol to form a mixture with a solid concentration of 50 mass %. The mixture was then subjected to wet milling using a ball mill to form a milled product. The balls used were zirconia balls with a diameter of 15 mm, 10 mm, 7 mm, or 3 mm. The balls were rotated at a speed of 300 rpm. The milling conditions were as shown in Table 1. The resulting milled product, which was a phosphor powder, was subjected to evaluation.

### Comparative Example 1

Fine particles of 3 μm or less were removed by wet classification from the milled product obtained in Example 8. A phosphor powder and a phosphor-containing composition were prepared as in Example 8, except for that process.

### (2) Evaluation

The phosphor powders obtained in Examples 1 to 12 and Comparative Example 1 were evaluated for various properties by the following procedures.

### Particle Size Distribution

The particle size distribution of the phosphor powder was measured using a laser diffraction particle size distribution analyzer MT3300EXII (MicrotracBEL Corporation). First, the interior of the circulation system of the analyzer was filled with a 99.5% ethanol solution, and the sample (phosphor powder) was then introduced into the analyzer such that the transmittance fell within the range of 60 to 95%. When introduced into the analyzer, the sample was dispersed by ultrasonication (40 W, 180 seconds). The particle size was then measured while the particles in the solvent in the measurement cell were circulated. The measurement was performed to determine a volume frequency particles size distribution curve and a volume cumulative particle size distribution curve, from which the cumulative volume frequency of particles with a diameter of less than 2.5 μm (fine particles) and the cumulative volume frequency of particles with a diameter of 2.5 μm or more and 10 μm or less (medium-diameter particles) were determined. The 20% cumulative diameter (D20), 50% cumulative diameter (D50), and 80% cumulative diameter (D80) of the particles were determined, and the particle size distribution ratio ((D80−D20)/D50) was calculated. The particle size analysis was performed under the following conditions.
Flow velocity: 80%
Ultrasonication: 40 W, 180 seconds
Set zero time: 10 seconds
Measurement time: 30 seconds
Number of times of measurement: 1
Transmission properties: Transparent
Particle refractive index: 2.46 (in Examples 1 to 8 and
Comparative Example 1)
Particle refractive index: 1.59 (in Examples 9 to 12)
Particle shape: Non-spherical
Solvent refractive index: 1.36

A volume frequency curve was also plotted with the common logarithm of particle diameter on the horizontal axis, volume frequency on the vertical axis, and the maximum volume frequency being normalized to 1. The area (peak area) enclosed by the volume frequency curve and the horizontal axis was then calculated.

Fluorescence Properties (Absorption Rate, External Quantum Efficiency, Internal Quantum Efficiency)

The resulting phosphor-containing composition was measured for internal quantum efficiency (IQE), external quantum efficiency (EQE), and absorption rate (Abs). During the measurement, LED light at 460 nm was applied to one surface of the phosphor-containing composition, and light from the other surface was measured using a spectroscope USB4000 (Ocean Insight).

Shown below are the equations for the calculation of the absorption rate, internal quantum efficiency, and external quantum efficiency of the phosphor excited with 460 nm light.

P₁ (λ) is the LED light spectrum at 460 nm, and P₂ (λ) is the sample spectrum. The area Li under the P₁ (λ) spectrum in the excitation wavelength range of 440 nm to 488 nm was calculated according to Equation (i) below. The resulting value was used as the excitation intensity. The area L₂ under the P₂ (λ) spectrum in the excitation wavelength range of 440 nm to 488 nm was calculated according to Equation (ii) below. The resulting value was used as the sample scattering intensity. The area E₂ under the P₂ (λ) spectrum in the excitation wavelength range of 489 nm to 800 nm was calculated according to Equation (iii) below. The resulting value was used as the sample fluorescence intensity.

$$\begin{matrix}[ Math . 2 ] & \\ {L}_{1} = {\int }_{440}^{488} {P}_{1} ( λ ) d λ & ( i )\end{matrix}$$

$${L}_{2} = {\int }_{440}^{488} {P}_{2} ( λ ) d λ \qquad ( ii )$$

$${E}_{2} = {\int }_{489}^{800} {P}_{2} ( λ ) d λ \qquad ( iii )$$

The absorption rate (Abs) was calculated according to Equation (iv) below as the ratio of the reduction in excitation light intensity to the intensity of excitation light incident on the sample. The external quantum efficiency (EQE) was the value calculated according to Equation (v) below by dividing the number Nₑₘ of photons of fluorescence emitted from the sample by the number Nₑₓ of photons of excitation light applied to the sample. The internal quantum efficiency (IQE) was the value calculated according to Equation (vi) below by dividing the number Nₑₘ of photons of fluorescence emitted from the sample by the number N_{abs} of photons of excitation light absorbed by the sample.

$$\begin{matrix}[ Math . 3 ] & \\ Abs = \frac{{L}_{1} - {L}_{2}}{{L}_{1}} & ( iv )\end{matrix}$$

$$EQE = \frac{{N}_{em}}{{N}_{ex}} = \frac{{E}_{2} - \frac{{L}_{2}}{{L}_{1}}}{{L}_{1}} \qquad ( v )$$

$$IQE = \frac{{N}_{em}}{{N}_{ab s}} = \frac{{E}_{2} - \frac{{L}_{2}}{{L}_{1}}}{{L}_{1} - {L}_{2}} \qquad ( vi )$$

### (3) Evaluation Results

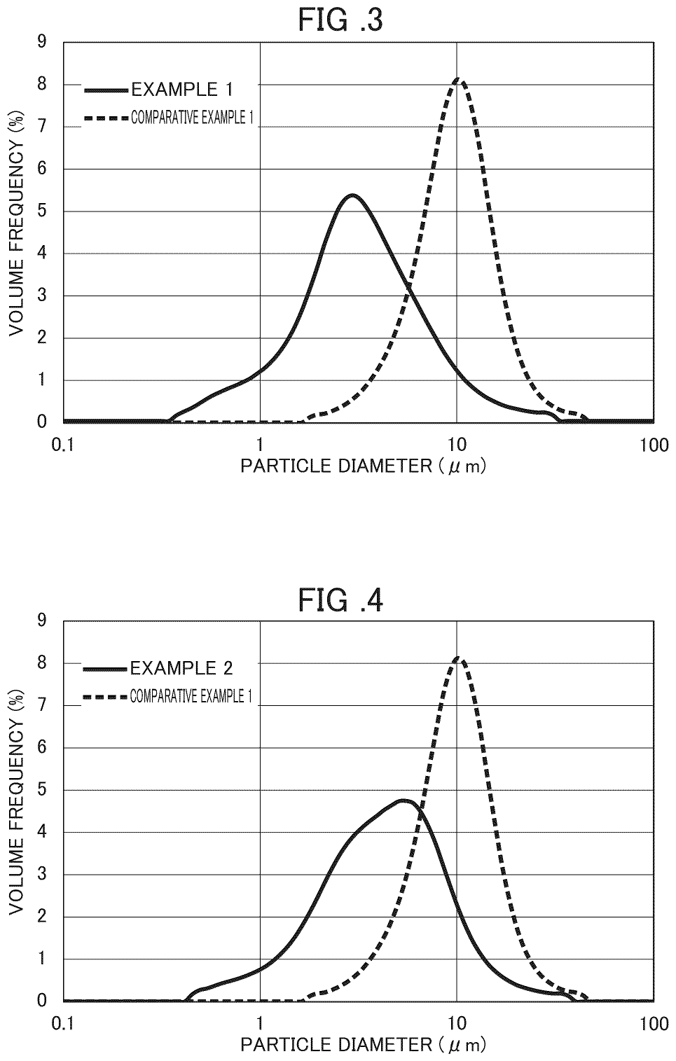

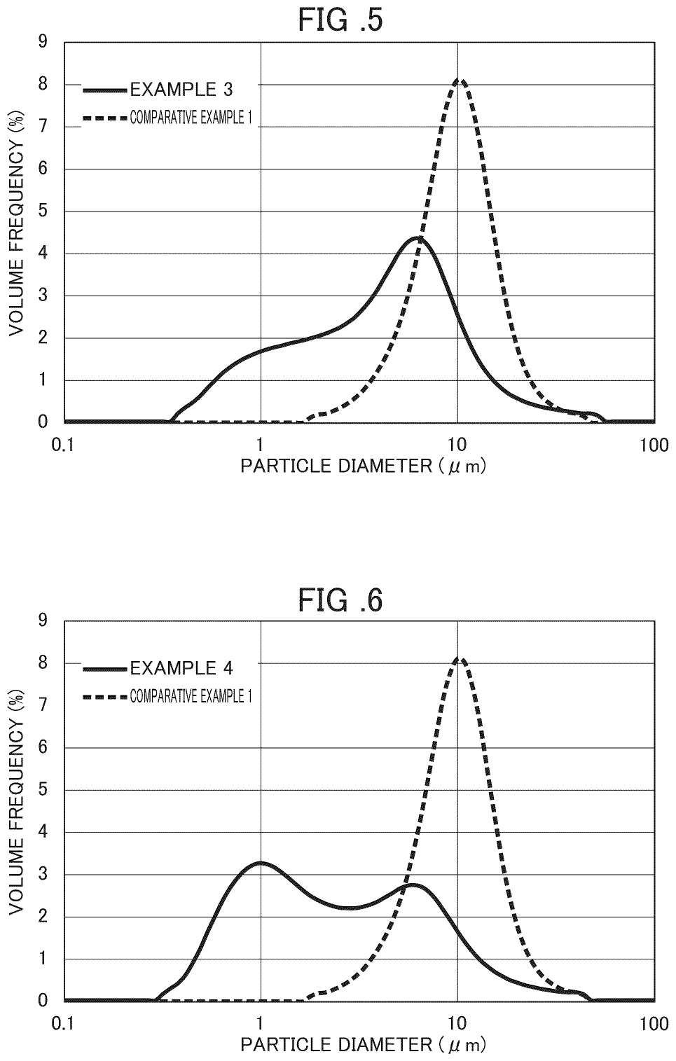

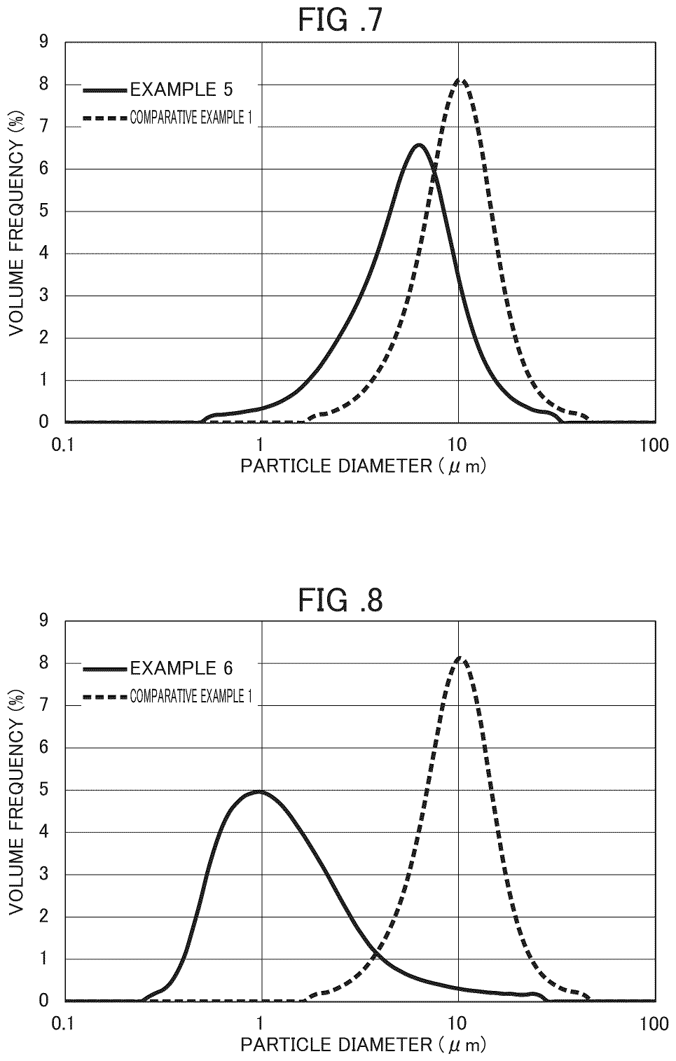

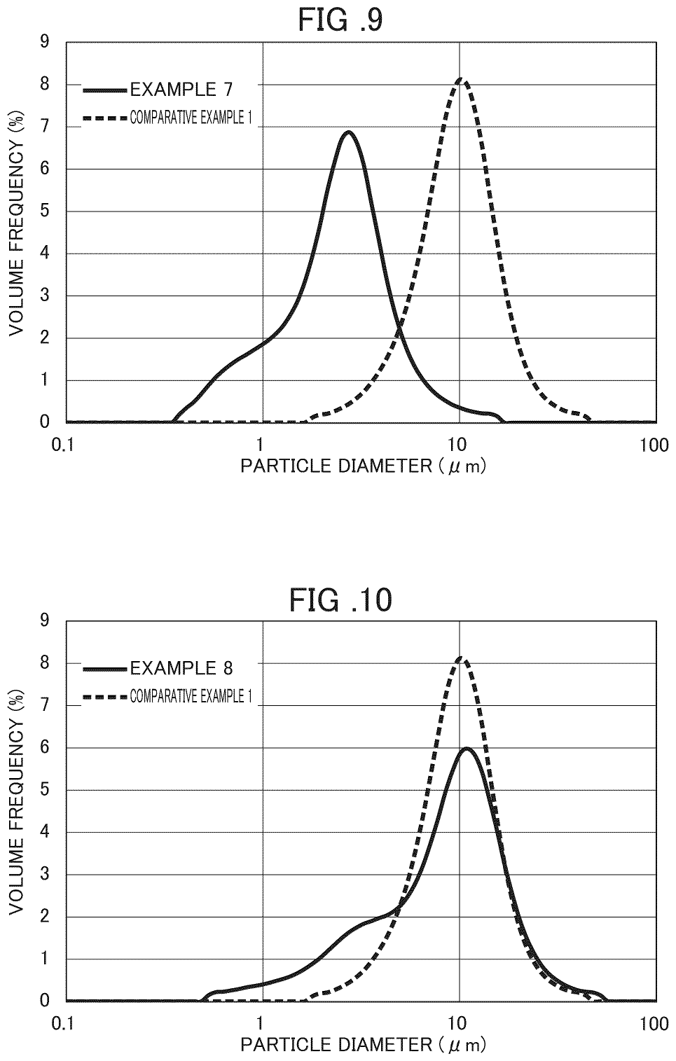

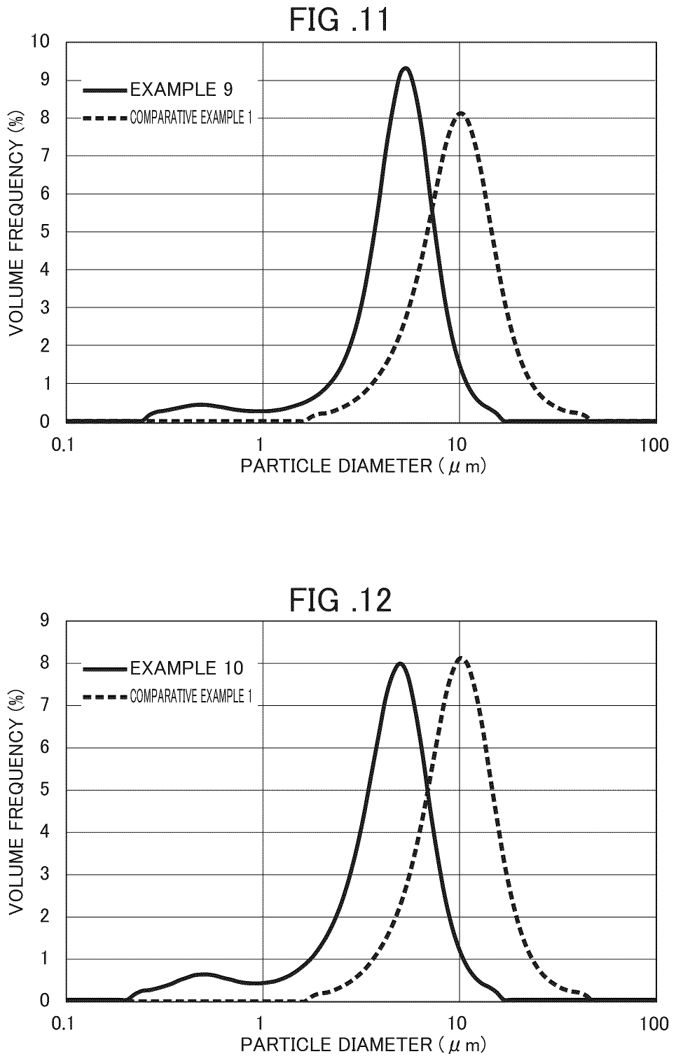

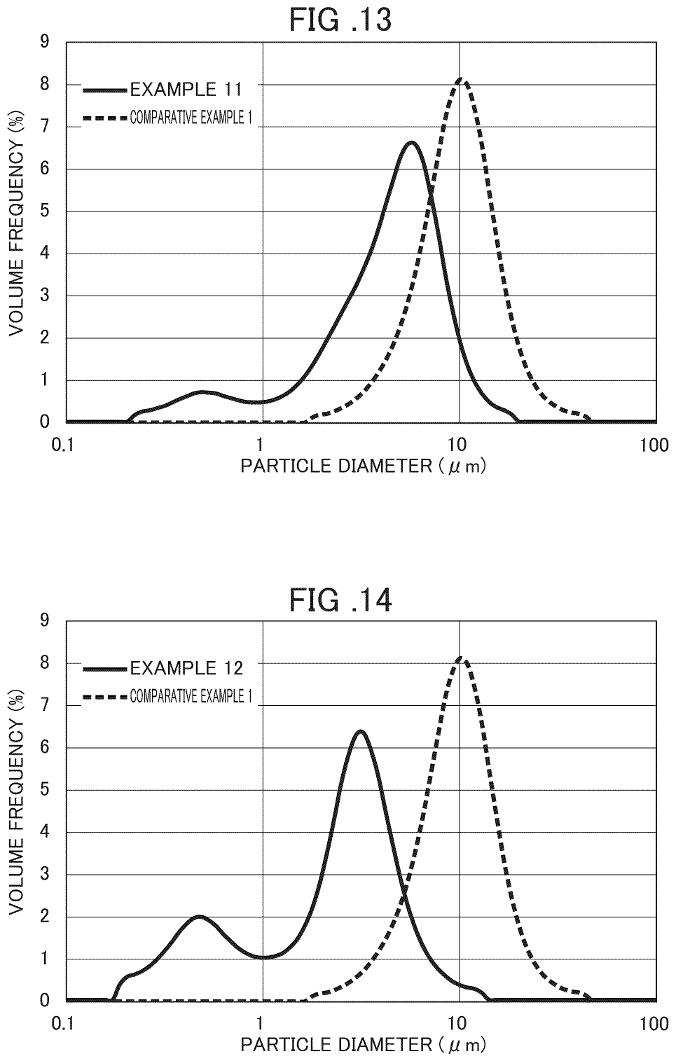

Table 2 summarizes the particle size distributions and fluorescence properties of the phosphor powders of Examples 1 to 12 and Comparative Example 1. FIGS. 3 to 14 show the particle size distributions (volume frequency distribution curves) of the phosphor powders.

Examples 1 to 12, in which the contents of the fine particles and the medium-diameter particles fall within the ranges according to the embodiment, showed high absorption rates and high internal quantum efficiencies. In contrast, Comparative Example 1 free of the fine particles showed a lower absorption rate than Examples 1 to 12.

TABLE 1
Conditions for milling to produce phosphor powder

| | Ball milling | | | | | Jet milling | | |
|---|---|---|---|---|---|---|---|---|
| | Amount of balls added (g) | | | | Ball | Gas | | Removal of |
| | 15 mm | 10 mm | 7 mm | 3 mm | milling | pressure | | fine |
| | diameter | diameter | diameter | diameter | time (h) | (MPa) | Feed gas | particles |
| Example 1 | 0 | 0 | 300 | 400 | 4 | — | — | Absent |
| Example 2 | 0 | 0 | 400 | 300 | 2 | — | — | Absent |
| Example 3 | 0 | 400 | 0 | 300 | 5 | — | — | Absent |
| Example 4 | 0 | 350 | 0 | 350 | 7 | — | — | Absent |
| Example 5 | 0 | 0 | 700 | 0 | 1.5 | — | — | Absent |
| Example 6 | 0 | 0 | 700 | 0 | 20 | — | — | Absent |
| Example 7 | — | — | — | — | — | 0.4 | N₂ | Absent |
| Example 8 | 500 | 0 | 0 | 200 | 5 | — | — | Absent |
| Example 9 | 0 | 0 | 400 | 300 | 1.5 | — | — | Absent |
| Example 10 | 0 | 0 | 300 | 400 | 2 | — | — | Absent |
| Example 11 | 0 | 400 | 0 | 300 | 1.5 | — | — | Absent |
| Example 12 | 0 | 0 | 500 | 200 | 15 | — | — | Absent |
| Comparative | 500 | 0 | 0 | 200 | 5 | — | — | Removal of |
| Example 1 | | | | | | | | particles of |
| | | | | | | | | 3 μm or less |

TABLE 2
Particle size distribution and fluorescence properties of phosphor powder

| | Particle size distribution | | | | | | | | | | |
|---|---|---|---|---|---|---|---|---|---|---|---|
| | | Cumulative | | | | | | | | | |
| | Cumulative | volume | Cumulative | | | | | | | | |
| | volume | frequency | volume | | | | | | Fluorescence properties | | |
| | frequency | of medium- | frequency | | | | | | | Internal | External |
| | of fine | diameter | of coarse | | | | | (D80 − | | quantum | quantum |
| | particles | particles | particles | Peak | D20 | D50 | D80 | D20)/ | Absorption | efficiency | efficiency |
| | (%) | (%) | (%) | area | (μm) | (μm) | (μm) | D50 | rate Abs | IQE | EQE |
| Example 1 | 34 | 59 | 7 | 19 | 1.7 | 3.0 | 5.5 | 1.3 | 56 | 65 | 37 |
| Example 2 | 23 | 66 | 11 | 21 | 2.1 | 4.1 | 7.3 | 1.2 | 52 | 67 | 35 |
| Example 3 | 31 | 54 | 15 | 23 | 1.4 | 4.2 | 8.0 | 1.6 | 66 | 52 | 35 |
| Example 4 | 52 | 38 | 10 | 31 | 0.9 | 2.2 | 6.4 | 2.5 | 66 | 49 | 32 |
| Example 5 | 11 | 74 | 15 | 15 | 3.1 | 5.4 | 8.4 | 0.96 | 52 | 58 | 31 |
| Example 6 | 82 | 16 | 2 | 20 | 0.7 | 1.1 | 2.2 | 1.4 | 72 | 43 | 31 |
| Example 7 | 48 | 50 | 1 | 15 | 1.3 | 2.4 | 3.6 | 0.97 | 51 | 58 | 30 |
| Example 8 | 10 | 44 | 46 | 17 | 3.8 | 8.7 | 14 | 1.2 | 49 | 65 | 31 |
| Example 9 | 11 | 85 | 4 | 13 | 3.0 | 4.8 | 6.8 | 0.8 | 45 | 66 | 30 |
| Example 10 | 17 | 80 | 3 | 13 | 2.6 | 4.3 | 6.1 | 0.8 | 46 | 63 | 29 |
| Example 1 | 20 | 74 | 6 | 15 | 2.3 | 4.5 | 6.8 | 1.0 | 42 | 65 | 27 |
| Example 12 | 45 | 54 | 1 | 16 | 0.7 | 2.5 | 3.9 | 1.3 | 51 | 49 | 25 |
| Comparative | 0.79 | 48 | 52 | 12 | 6.3 | 9.4 | 13 | 0.75 | 33 | 72 | 24 |
| Example 1 | | | | | | | | | | | |

1. A phosphor powder comprising, as measured by laser diffraction scattering particle size distribution measurement: particles with a particle diameter of less than 2.5 μm at a cumulative volume frequency of 10% or more; and particles with a particle diameter of 2.5 μm or more and 10.0 μm or less at a cumulative volume frequency of 10% or more and 90% or less, the phosphor powder having a volume particle size distribution with a 50% cumulative diameter (D50) of 10.0 μm or less.

2. The phosphor powder according to claim 1, wherein the phosphor powder has a volume frequency distribution curve plotted with the common logarithm of particle diameter on a horizontal axis, volume frequency on a vertical axis, and a maximum volume frequency being normalized to 1 and has a peak area, which is an area enclosed by the volume frequency distribution curve and the horizontal axis, of 12 or more.

3. The phosphor powder according to claim 1, wherein, as measured by laser diffraction scattering particle size distribution measurement, the phosphor powder has a volume particle size distribution with a particle size distribution ratio of 0.7 or more, wherein the particle size distribution ratio is calculated as (D80−D20)/D50 from a 20% cumulative diameter (D20), a 50% cumulative diameter (D50), and an 80% cumulative diameter (D80) of the volume particle size distribution.

4. The phosphor powder according to claim 1, wherein the phosphor powder comprises a luminescent center; and at least one of a crystal matrix comprising gallium (Ga), sulfur (S), and at least one metal element selected from the group consisting of barium (Ba), strontium (Sr), and calcium (Ca) or a crystal matrix comprising sulfur (S) and at least one metal element selected from the group consisting of barium (Ba), strontium (Sr), and calcium (Ca).

5. A phosphor-containing composition comprising a phosphor powder comprising, as measured by laser diffraction scattering particle size distribution measurement: particles with a particle diameter of less than 2.5 μm at a cumulative volume frequency of 10% or more; and particles with a particle diameter of 2.5 μm or more and 10.0 μm or less at a cumulative volume frequency of 10% or more and 90% or less, the phosphor powder having a volume particle size distribution with a 50% cumulative diameter (D50) of 10.0 μm or less.

6. The phosphor-containing composition according to claim 5, wherein the phosphor powder has a volume frequency distribution curve plotted with the common logarithm of particle diameter on a horizontal axis, volume frequency on a vertical axis, and a maximum volume frequency being normalized to 1 and has a peak area, which is an area enclosed by the volume frequency distribution curve and the horizontal axis, of 12 or more.

7. The phosphor-containing composition according to claim 5, wherein, as measured by laser diffraction scattering particle size distribution measurement, the phosphor powder has a volume particle size distribution with a particle size distribution ratio of 0.7 or more, wherein the particle size distribution ratio is calculated as (D80−D20)/D50 from a 20% cumulative diameter (D20), a 50% cumulative diameter (D50), and an 80% cumulative diameter (D80) of the volume particle size distribution.

8. The phosphor-containing composition according to claim 5, wherein the phosphor powder comprises a luminescent center; and at least one of a crystal matrix comprising gallium (Ga), sulfur (S), and at least one metal element selected from the group consisting of barium (Ba), strontium (Sr), and calcium (Ca) or a crystal matrix comprising sulfur (S) and at least one metal element selected from the group consisting of barium (Ba), strontium (Sr), and calcium (Ca).

9. A light-emitting element comprising: the phosphor-containing composition according to claim 5; and an excitation source.

10. A light-emitting device comprising the light-emitting element according to claim 9.
